(19) United States
(12) Patent Application Publication
(10) Pub. No.: US 2025/0327184 A1
(43) Pub. Date: Oct. 23, 2025

(54) Apparatus and Method for Plasma Enhanced Chemical Vapour Deposition

(71) Applicant: LeydenJar Technologies B.V., Leiden (NL)

(72) Inventors: Pavel Kudlacek, Leiden (NL); Arjen Peter Didden, Leiden (NL)

(73) Assignee: LeydenJar Technologies B.V., Leiden (NL)

(21) Appl. No.: 18/845,857

(22) PCT Filed: Mar. 10, 2023
(86) PCT No.: PCT/NL2023/050119

§ 371 Date: Sep. 10, 2024

(30) Foreign Application Priority Data
Mar. 11, 2022 (NL) 2031258

(51) Int. Cl. C23C 16/511; C23C 16/24; C23C 16/455; C23C 16/458; C23C 16/46

(52) U.S. Cl. CPC C23C 16/511; C23C 16/24; C23C 16/455; C23C 16/458; C23C 16/463

(57) ABSTRACT

The present disclosure relates to a process for simultaneous deposition onto two opposite sides of a sheetlike substrate using a plurality of linear plasma sources, comprising the steps: providing a reaction chamber comprising a gaseous atmosphere; and at least two linear plasma sources positioned in the chamber,

introducing a sheetlike substrate comprising two elongate sides into the reaction chamber, and moving the substrate between the at least two linear plasma sources at a first velocity; supplying power to the linear plasma sources to generate linear plasmas in the vicinity of each side of the substrate;

introducing at least one reactant mixture, at a first gas flow rate, into the reaction chamber on each of the respective opposite sides of the substrate, the composition of the mixture being such that, upon contact with the plasma, the reactant mixture decomposes and generates a chemical reactant species capable of being deposited as a film onto the corresponding side of the substrate;

allowing the chemical reactant species to simultaneously be deposited onto the first and second opposite sides of the substrate at the same position with respect to the substrate movement direction;

to obtain a substrate comprising a coated homogeneous film of desired thickness on the opposite sides of the substrate.

This disclosure relates to an apparatus and method for simultaneous plasma enhanced chemical vapour deposition on two sides of a substrate.

### BACKGROUND

Plasma enhanced chemical vapour deposition (PECVD) is widely employed in high volume coating of substrates with thin layers of deposited material. PECVD is used to deposit thin films from a gaseous vapour state onto substrates where it forms a solid state. The deposition process involves chemical reactions which occur after introductions of the feedstock gasses to the plasma. The plasma is typically generated by microwave radiation, or by radio frequency (RF) or direct current (DC) discharge between two electrodes, with the space between the electrodes comprising the reacting gasses.

The deposition of thin-film coatings is used in various applications, such as electronics (battery materials, chips, etc), corrosion-resistant and tribological coatings, such as refractory films (titanium or aluminium nitrides, carbides and oxides), coatings having optical (anti-reflection, Solar-protection, filter, etc.) properties, coatings providing other biological or physiochemical properties (antimicrobial, self-cleaning, hydrophilic, hydrophobic, oxygen impermeable packaging layer etc.), and conductive films for various applications (photovoltaics, LEDs, OLEDs, organic photovoltaics, etc.).

The substrates in question may be of various types: glass, steel, copper films, ceramics, organic polymers, thermoplastics, etc.

For most industrial applications deposition of a film of homogeneous depth onto a substrate is desirable, especially for continuous processes. One approach employed in the art is the use of linear plasma sources for PECVD. These linear plasma sources typically comprise a rod-shaped antenna, which is arranged in a dielectric tube. This combination of rod-shaped antenna and dielectric tube is often referred to as the inner conductor of a coaxial conductor assembly. The outer conductor of is then formed by the plasma generated on the dielectric tube. This coaxial conductor arrangement forms the actual plasma source, and is often surrounded by a wall with an opening, through which the plasma emerges in the direction of a substrate to be coated. The plasma source extends along an axis that extends along the axis of the rod shaped antenna with a defined length, with the opening in the wall typically having a width shorter than the length of the plasma source, thereby providing a linear plasma source. Examples of such sources can be found in DE 19812558 B4. An example of the method that employs a linear plasma source to deposit a homogeneous layer onto a roll of substrate is provided by U.S. Pat. No. 5,114,770 A.

The dielectric tubes must be able to withstand extended periods at the high temperatures that plasma generation entails. Materials typically used possess a melting point above 1000° C., such as quartz with a melting point of 1650 (±75° C.)

During PECVD processes using linear plasma sources, a first gas, which contains little to no chemically active deposition material of the process, is often introduced into the plasma source near the antenna, while a second gas, which contains most or all of chemically active deposition material of the process, is introduced into the plasma source near a substrate surface of the to be treated substrate.

With the rapid development of plasma technology in the fields of large-scale integrated circuits, solar cells, plasma display devices, diamond-like carbon and pure diamond films and battery materials the industry requires a method and apparatus that can deposit onto large areas in a uniform manner, preferably at low pressure and with high plasma density. Linear source PECVD has many advantages: the structure is relatively simple to construct, and there is no impurity pollution caused by electrode insertion; high plasma density can be achieved. In particular, because of its linear structure, if plasma is uniformly provided along the axial direction of the linear plasma source, a substrate passed past such a linear plasma source at a uniform distance will be uniformly coated with a deposition layer. This is a considerable advantage for roll-to-roll processes and for continuous processes where large number of substrates are continuously passed past a linear PECVD source.

As will be readily understood, a long linear plasma source along which a uniform plasma can be provided advantageously allows for either a wide substrate roll to be coated or for a greater number of substrates to be passed past the deposition source in a given time period.

For a range of commercial products it is preferable or necessary to deposit thin films on two sides of a thin substrate. These products include electrode materials, where deposition of a lithium ion accommodating layer on both sides of an electron conducting metal substrate can afford electrode materials with superior performance. These products also include product packaging, where deposition of thin oxygen and water impermeable layers onto both sides of a plastic substrate afford packaging material with superior oxygen and water barrier performance.

As will be readily appreciated, PECVD entails substantial heating of the substrate during deposition. The main sources of heat for PECVD processes are radiative heating from the plasma, heat generated by ion and atom impingement, condensation heating and potentially also exothermic reactions at the surface. This has a significant disadvantage in that the hot once-coated substrate must be cooled before depositing the second coating. This further heating can lead to the following problems: (1) cracking of the first deposition layer, (2) de-lamination/de-attachment of the first deposition layer from the substrate, (3) warping of the substrate due to uneven co-efficient of thermal expansion of the substrate and the deposited material, (4) destruction of micro- or nano-structured morphologies of the deposited material due to annealing or stress/strain occasioned by thermal expansion/contraction. The present state of the art is to pass the first side of a substrate past a first PECVD deposition station, then pass the substrate over a cooling roller and then pass the second side of a substrate past a second PECVD deposition station. This is disadvantageous as the cooling roller either (a) need to be located within the PECVD deposition chamber or (b) the reaction chamber requires vacuum ports/vacuum locks for the surface coated sheet-like substrate. The disadvantages of locating the cooling roller within the reaction chamber are as follows: (i) frequent interruption of continuous processes to remove parasitically deposited material from the rollers, which typically foul the rotation points; and (ii) decreased quality of the coating from evaporation of components of the joint lubrication from the cooling roller becoming incorporated as impurities into the coating. The disadvantages of using vacuum ports for the surface coated sheet-like substrate is physical contact of the hot coating with the vacuum port degrades the uniformity of the deposited layer.

A further disadvantage of the state of the art, involving sequential deposition onto two sides of a substrate is that such systems require large reactor volumes to encompass the distributed deposition means. This is disadvantageous in that larger deposition chambers require longer periods of pump-down time to attain reduced pressures typically employed in PECVD and consequently, such sequential deposition strategies require more energy to run.

An outstanding challenge in the field of plasma assisted chemical vapour deposition is therefore the provision of an apparatus and method to coat substrates on two sides that does not suffer from these problems.

In the state of the art, cooling drums are often used to mitigate the heating of the substrate. These cooling drums may be used inline in roll-to-roll processes after a deposition station to try and cool the substrate to the same temperature as before entering the deposition station, which disadvantageously imposes higher process costs and requires a greater surface area/height/volume for suitable deposition apparatus. The use of an interstitial chill roller (7) between a first plasma enhanced chemical vapour deposition onto a first surface of a sheet like substrate and a second plasma enhanced chemical vapour deposition onto the same surface of a sheet like substrate is disclosed in EP 1206908 A1. It is noted that EP 1206908 A1 is not suitable for deposition onto a metallic sheet like substrate as the microwave radiation cannot pass through such a substrate without excessive heating.

An alternative approach in the art is that the material may be deposited onto one side of a sheet-like substrate whose second side is in thermal contact with a cooling drum. Cooling drums are typically actively cooled by means of liquid coolant flow through the drum. The rate of cooling is a function of the actual contact area, the rate of cooling of the drum by the cooling means, the thermal conductivity of the drum and the thermal conductivity of the substrate. Such deposition means suffer from the disadvantage of excessive thermal gradients through the sheet like substrate. For attempts to control deposition by controlling the temperature of the substrate during deposition, the difference in rate of cooling a substrate with and without an interstitial deposition layer must be taken into account, which disadvantageously complicates manufacturing processes though requiring continuous in-line detection methods that increase the cost of manufacture. This also imposes greater cost and complexity on the manufacturing apparatus. Alternative cooling means may also be employed, such as cooling panels as disclosed in U.S. Pat. No. 5,514,217 A.

An outstanding challenge in the field of plasma assisted chemical vapour deposition is therefore the provision of a simplified apparatus and method to deposit two identical homogeneous coating layers onto two sides of a substrate.

### BRIEF SUMMARY OF THE DISCLOSURE

In accordance with the present disclosure there is provided a process for simultaneous deposition onto two opposite sides of a substrate using a plurality of linear plasma sources. Further embodiments are disclosed in the claims appended to the present specification.

### DESCRIPTION OF THE DRAWINGS

Embodiments of the disclosure are further described hereinafter with reference to the accompanying drawings, in which:

FIG. 1 depicts a side-on cross-sectional view of an apparatus according to an aspect of the disclosure engaged in a process according to another aspect of the disclosure.

FIG. 2 depicts a side-on cross-sectional view of an experimental setup inside a vacuum chamber.

FIG. 3 shows the measured temperature dependency in the line-up of FIG. 2 versus the net power input.

FIG. 4 plots the net power input versus the fourth power of temperature (T⁴, in K⁴).

### DETAILED DESCRIPTION

A first aspect of the disclosure concerns a process for simultaneous deposition onto two opposite sides of a substrate using a plurality of linear plasma sources, comprising the steps:
Introducing a sheet-like electrically conductive substrate comprising two sides into, or making the substrate run through a reaction chamber comprising two ends and filled with an atmosphere, in which at least two linear plasma sources are placed, the substrate being introduced between the at least two linear plasma sources;
Supplying power to the linear plasma sources to generate linear plasmas on each side of the substrate;
Introducing at least one mixture into the reaction chamber, on each opposite side of the substrate, the composition of the mixture being such that, upon contact with the plasma, the mixture decomposes and generates species capable of being deposited as a film onto the corresponding side of the substrate;
Simultaneously depositing a film onto the first and second opposite sides of the substrate at the same position along the substrate;
Radiatively cooling the substrate between the first deposition zone and the second deposition zone;
Moving the substrate past the at least two linear plasma sources at a first velocity, whilst providing the at least one mixture at a first flow rate, to obtain a homogeneous film of desired thickness on the opposite sides of the substrate.

A first advantage of the process of the disclosure is that radiative cooling occurs before deposition onto the second side of the substrate, avoiding (i) use of cooling roller and (ii) excessive thermal gradients across the substrate. This advantageously provides a simplified process for providing known substrates that are coated on opposite sides of the substrate that requires less maintenance. It also advantageously provides a route to substrates coated on both sides, where the deposited material cannot survive a heating and cooling cycle after deposition that occurs with a second plasma enhanced deposition step.

A second advantage of the process of the disclosure is the process requires a smaller reaction (deposition) chamber volume than sequential processes known in the art, and as such requires less energy to operate.

Suitable linear plasma sources may be selected from linear arc plasma sources, internal-type linear inductively coupled plasma sources and microwave linear plasma sources.

Suitable internal-type linear inductively coupled plasma sources feature a linear metal antenna section within a coaxial dielectric tube section. The antenna sections may be provided as a single copper metal rod, or may be provided as more complicated serpentine types, comb/double-comb types, U-shaped types. Alternative geometries can be considered. The antenna is provided a high radio-frequency electric current and

Suitable linear microware plasma sources are described in DE 19812558 A1, DE 19503205 C1, WO 2012062754 A1, DE10 2018 110392 and DE 102010027619 B3. The linear microwave plasma sources preferably comprise: a linear antenna, an insulating tube fitted around the linear antenna and two microwave emitters arranged at each end of the linear antenna as described in DE 19503205 C1. These components are arranged so that both microwave emitters can transmit microwaves to be received by the same antenna. This provides the advantage that the thermal energy provided by the antenna to the plasma source is substantially uniform along the length of the antenna. This results in an apparatus capable of depositing thin layers to a substrate uniformly along the axis of the antenna.

Alternatively, and equally preferred, the linear microwave plasma sources preferably comprise: a plurality of closely bundled linear antennas, an insulating tube fitted around the linear antenna and two microwave emitters arranged at each end of the plurality linear antenna as described in DE 102010027619 B3. This also provides the advantage that the thermal energy provided by the antenna to the plasma source is substantially uniform along the length of the parallel antennas. This results in an apparatus capable of depositing thin layers to a substrate uniformly along the common axis of the plurality of antennas.

A particularly preferably linear plasma source in one in which a linear antenna is fed microwave radiation by a microwave radiation from a microwave generator to an end of the linear plasma source proximal to the microwave generator whilst microwave radiation is provided to the other, distal end of the antenna by a wave guide connected to the microwave generator.

Suitable radiative cooling means may optionally be suitably selected from plate-shaped radiation absorbers. An example of a suitable radiative cooling means is a plate-shaped stainless steel radiation absorber with a roughened outer surface. The roughened exterior increases thermal absorptivity. The high thermal conductivity of the steel allows for heat to be rapidly conveyed away from the absorbing surface, increasing the efficiency of the cooling. The radiative cooling means may optionally be configured to additionally allow heat to be rapidly conveyed away from the absorbing surface by means of circulating a coolant within the radiative cooling means. Suitable coolants such as water, refrigerant, or oil may be selected.

A first embodiment according to the first aspect of the disclosure relates to a process wherein a composition of the at least one mixture introduced into the reaction chamber on each side of the substrate is identical. This advantageously allows identical material to be deposited on opposite sides of the substrate to afford coatings on opposite sides of the substrate with identical thicknesses and thermal histories.

This embodiment is particularly advantageous for providing metallic foils coated with lithium storage material, such as amorphous silicon or nanostructured silicon. The lack of a heating and cooling cycle of the deposited lithium storage material helps avoid delamination of the deposited lithium storage material from the metal foil and also avoids cracking/warping/annealing of the deposited lithium storage layer. The uniform layer depth avoids swelling due to absorption of lithium leading to delamination of material, increasing the charge-cycle lifetime of batteries comprising such coated foils.

A second embodiment according to the first aspect of the disclosure relates to a process wherein the at least one mixture introduced into the reaction chamber on each side of the substrate is at least a first mixture and a second mixture, which are different, and generate species capable of being deposited as a film onto a corresponding side of the substrate. The mixtures introduced into the reaction chamber on each side of the substrate are confined in two separate zones by mechanical barriers. The substrate itself may form part of these mechanical barriers. This advantageously allows for the formation of substrates with a different coating layer on opposite sides of the substrate layer in a single deposition station. This results both in a time saving and a space saving in manufacture.

The process according to the first embodiment preferably utilises linear plasma sources selected linear microwave plasma sources, more preferably the linear microwave plasma sources additionally comprise a shielding manifold with an opening. The shielding manifold can be configured to have only one opening or a plurality of openings. Suitable shielding manifolds may comprise a plasma source wall as disclosed in U.S. Pat. No. 10,685,813 B2. Preferably, the process according to the first aspect employs linear microwave plasma sources, wherein the microwaves have a frequency in the range of from 0.9 to 5.8 GHZ, and more preferably from 2.0 to 3 GHZ, most preferably from 2.40 to 2.45 GHz. The microwave radiation may be supplied to the linear microwave plasma source as described in DE 4136297 A1.

Preferably, the process according to the first aspect is conducted at a pressure of 0.05 to 0.5 mbar.

Preferably, the process according to the first aspect has a dynamic deposition rate of from 5 to 200 nm·m·s⁻¹, more preferably from 10 to 150 nm·m·s⁻¹, yet more preferably from 20 to 100 nm·m·s⁻¹ and most preferably from 25 to 75 nm·m·s⁻¹.

Preferably, the process according to the first aspect is a process for deposition onto opposite sides of a film, (i.e. wherein the substrate is a film) with a width of from 100 to 1800 mm, more preferably a width of from 300 to 1500 mm, most preferably a width of from 600 to 1200 mm.

Preferably, the process according to the first aspect is a process for deposition onto opposite sides of a film, (i.e. wherein the substrate is a film) the film has a length of from 100 to 2000 m, more preferably a length of from 300 to 1200 m, most preferably a length of from 600 to 1200 m.

Preferably the substrate of the process comprises metal and/or polymers. The process according to claim 1, where the substrate comprises metal, metal alloy and/or electrically conductive polymers, preferably the substrate comprises metal and/or metal alloy, most preferably the substrate consists of metal and/or metal alloy

Most preferably, the process according to the first aspect is a roll-to-roll process.

In a preferable embodiment of the first aspect, the process is a process for simultaneous deposition of a lithium storage material onto two opposite sides of a substrate using a plurality of linear plasma sources. Preferably, the lithium storage material is selected from amorphous silicon, silicon nitride, silicon carbide, silicon oxide or nanostructured silicon, more preferably amorphous silicon or nanostructured silicon, most preferably nanostructured silicon.

In this embodiment, the substrate is a film. The film preferably has a thickness of from 2 to 100 μm, more preferably a thickness of 4 to 50 μm, even more preferably from 6 to 30 and most preferably a thickness of 10 to 20 μm.

The substrate film comprises an electron conducting material.

The substrate film may be a laminate of multiple different materials, comprising one or more an electron conducting materials. Preferably, the one or more electron conducting materials are selected from copper, titanium, nickel or stainless steel.

A suitable laminate material may comprise an inner polymer film laminated with an electron conducting material. Suitable polymers are high-temperatures thermoplastics, which are able to tolerate the high temperatures of deposition. Preferably such high temperature thermoplastics are selected from polyether ether ketone (PEEK), polyethylenimine (PEI), polyimide (PI), polyphenylene sulfide (PPS), polyethersulfone (PES or PESU), polyphenylsulfone (PPSU), polysulfone (PSU), polyamide-imide (PAI) or combination thereof, more preferably polyether ether ketone (PEEK). The electron conducting material may be selected from any suitable metal of metallic alloy. More preferably, the electron conducting material is selected from copper, titanium, nickel or stainless steel. A particularly preferred embodiment is a polymer film laminated on both sides with metallic copper foil. An even more particularly preferred embodiment is a PEEK polymer film laminated on both sides with metallic copper foil.

A preferable laminate material comprises an inner metallic foil laminated with an electron conducting material. The inner metallic foil may be selected from any suitable metal or metallic alloy. Preferably, the inner metallic foil is selected from copper, titanium, nickel or stainless steel. The electron conducting material may be selected from any suitable metal of metallic alloy. Preferably, the electron conducting material is selected from copper, titanium, nickel or stainless steel. In a particularly preferred embodiment, the substrate foil is a copper foil laminated between two nickel layers.

Preferably the substrate film is a metallic foil. The metallic foil may be composed of a pure metal or an alloy. More preferably, the metallic foil substrate comprises copper, titanium, nickel or stainless steel. Most preferably the metallic foil substrate is a copper foil.

The deposited material is a film with a thickness of from 2 to 100 μm, more preferably a thickness of 4 to 50 μm, even more preferably from 10 to 30 and most preferably a thickness of 15 to 20 μm.

The deposited material is any material that can store lithium ions. The deposited material is preferably selected from amorphous silicon, silicon nitride, silicon carbide, silicon oxide or nanostructured silicon, more preferably amorphous hydrogenated silicon or nanostructured silicon, most preferably nanostructured silicon. Most preferably, the process is a process for coating a substrate in an amorphous layer of columnar silicon in which nano-crystalline regions exist.

Preferably, the process of this embodiment is a process of coating a substrate to provide an electrode material. More preferably this embodiment is a process of coating a substrate to provide an anode. More preferably still, this embodiment is a process of coating a substrate to provide an anode for a lithium-ion battery.

More preferably, the process is a process for coating a substrate in an amorphous layer of silicon, preferably wherein the process is a process for coating a substrate in an amorphous layer of nano-structured silicon in which nano-crystalline regions exist, most preferably wherein the process is a process for coating a substrate in an amorphous layer of columnar silicon in which nano-crystalline regions exist

Where the deposited material is a inorganic oxide (such as SiO₂), the material is deposited s a film with a thickness of from 5 to 50 μm, more preferably a thickness of 10 to 45 μm, even more preferably from 15 to 40 and most preferably a thickness of 20 to 30 μm.

In an alternative preferable embodiment of the first aspect, the process is a process for simultaneous deposition of a corrosion resistant layer onto two opposite sides of a substrate using a plurality of linear plasma sources.

In an alternative preferable embodiment of the first aspect, the process is a process for simultaneous deposition of an optically active layer onto two opposite sides of a substrate using a plurality of linear plasma sources, more preferably deposition of an anti-reflective layer.

In an alternative preferable embodiment of the first aspect, the process is a process for simultaneous deposition of an electronically conductive material onto two opposite sides of a substrate using a plurality of linear plasma sources, more preferably a conductive metal oxide film, most preferably wherein the metal oxide is selected from the group consisting of zinc oxide, titanium oxide, tin oxide, zirconium oxide, and cerium oxide.

Preferably, the process according to the first aspect is one wherein the mixture introduced into the reaction chamber on one or both sides of the substrate is introduced as a first gas and as a second gas. This advantageously allows for plasma forming gases to be supplied to the linear plasma source and deposition material forming gases to be supplied proximal to the plasma, which is more atom and energy efficient than providing a combined mixture proximal to the linear plasma source.

More preferably, the first gas comprises a chemically inert carrier gas, preferably wherein the inert carrier gas is selected from nitrogen, helium, argon or combination thereof, more preferably the inert carrier gas is selected from nitrogen, helium, argon or a combination of these gasses, most preferably the inert carrier gas is argon.

Yet more preferably, the first gas additionally comprises a reactive gas. The reactive gas is preferably selected from hydrogen, oxygen ammonia, nitrous oxide, nitrogen trifluoride, methane, acetylene, ethane, ethene, propane, propene or any combination of these gasses, most preferably hydrogen.

Particularly preferable combinations of gasses present in the first gas are a chemically inert carrier gas selected from nitrogen, helium, argon, or a combination of these gasses and a reactive gas selected from hydrogen, oxygen, ammonia, nitrous oxide, nitrogen trifluoride, methane, acetylene ethane, ethene, propane, propene. The most preferable combination being that the first gas comprises only a chemically inert carrier gas of argon and a reactive gas of hydrogen.

Preferably, the second gas comprises a precursor gas, more preferably the precursor gas is selected from SiH₄, SiH₃Cl, SiH₂Cl₂, SiHCl₃, SiCl₄, Si₂H₆, Si₂Cl₆, Si₃H₈, SiEt₂H₂ or cyclohexasilane.

More preferably, the second gas is a precursor gas, more preferably a precursor gas selected from SiH₄, SiH₃Cl, SiH₂Cl₂, SiHCl₃, SiCl₄, Si₂H₆, Si₂Cl₆, Si₃H₈, SiEt₂H₂ or cyclohexasilane.

In a most preferably embodiment, the process is one wherein the first gas consists of a chemically inert carrier gas and a reactive gas and the second gas is a precursor gas, wherein the chemically inert carrier gas is argon, the reactive gas is hydrogen, and the precursor gas is SiH₄. This process according to the most preferable embodiment advantageously allows for the deposition of lithium storage materials with exceptionally high atom and energy efficiency and a thermal history of hot deposition and cooling, without an additional heating and cooling step consistent with subsequent deposition. Films deposited in this manner are believed to possess beneficial morphologies and increased physical stability.

The disclosure also relates to a product obtainable by the aspect or any embodiment thereof described above.

The disclosure also relates to an apparatus for simultaneous plasma enhanced chemical vapour deposition onto two opposite sides of a sheet-like substrate, comprising:
A reaction chamber;
Transport means and support means for introducing a substrate into a chamber;
A plurality of linear plasma sources, wherein at least a set of two linear plasma sources are arranged to allow simultaneous deposition onto two opposite sides of a substrate;
Power supply means for supplying power to the linear plasma sources;
Radiative cooling means;
Gas supply manifold for introducing the at least one mixture of reactive species to the reaction chamber, and
   the transport means, support means, and plurality of linear plasma sources are arranged to allow the substrate to be moved past the plurality of linear plasma sources.

In a preferable embodiment, the apparatus is one wherein the linear plasma sources are linear microwave plasma sources, and the power supply means additionally comprises a microwave generator.

The apparatus is preferably one wherein the means for introducing the at least one mixture of reactive species to the reaction chamber is a gas supply manifold, preferably wherein the gas supply manifold comprises one or more first gas conduit(s) provided with first gas ports for providing one or more first gaseous substances to a reactor, one or more second gas conduit(s) provided with second gas ports for providing one or more second gaseous substances to a reactor and one or more exhaust gas conduit(s) provided with exhaust gas port(s) for removing one or more exhaust gaseous substances from a reactor;

The apparatus is preferably one wherein the means for introducing the at least one mixture of reactive species to the reaction chamber is a gas supply manifold, preferably wherein the gas supply manifold comprises one or more first gas conduit(s) provided with first gas ports for providing one or more first gaseous substances to a reactor, one or more second gas conduit(s) provided with second gas ports for providing one or more second gaseous substances to a reactor and one or more exhaust gas conduit(s) provided with exhaust gas port(s) for removing one or more exhaust gaseous substances from a reactor.

In a preferred embodiment, the reaction chamber is vertically disposed to allow the substrate to be treated to pass through the plasma deposition zone vertically. This optional disposition advantageously allows for reduction in accidental deposition of parasitically deposited material falling onto the substrate, leading to damage of the deposited surface.

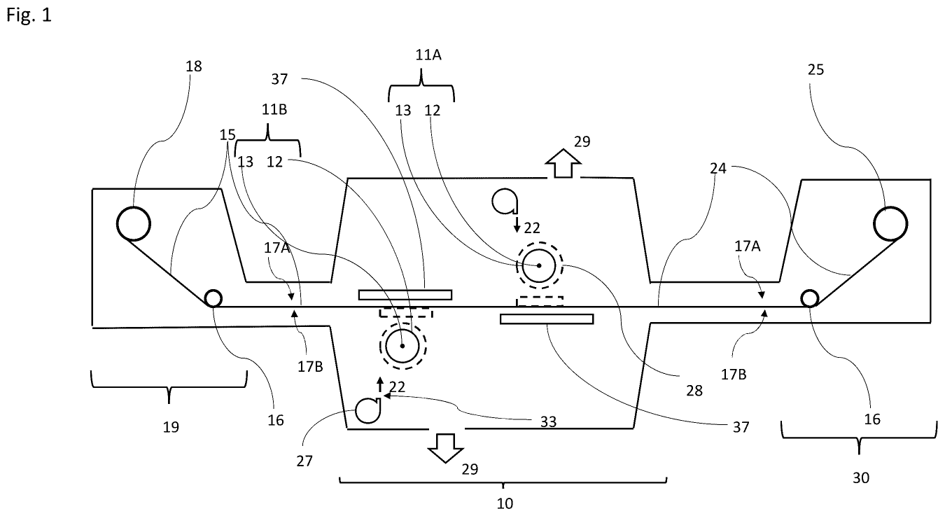

Preferably, the apparatus (26) is configured such that the radiative cooling plates are located opposite to the linear plasma sources (11). An apparatus with the cooling plates located opposite to the linear plasma sources (11) is believed to be particularly effective at cooling. As depicted in FIG. 1, the radiative cooling plates may optionally be located in the region directly opposite the linear plasma source (11), and extend in one direction parallel to the substrate. and are believed to be particularly effective at cooling the substrate. Without wishing to be bound by any particular theory, it is believed that radiative cooling scales with T⁴ (T denoting temperature in Kelvin), and as the substrate is hottest closest to the linear plasma sources during deposition, it is believed that radiative cooling is most effective when the radiative cooling plates are located directly opposite to the linear plasma sources. It is noted that the cooling of the plasma source also may cool the foil, and vice versa, as applicants found that at high-temperature, foils may emit infrared radiation towards the cooling plates above, and back to the source, and hence should be calculated into the cooling capacity.

A final aspect of the disclosure relates to a process according to any of the process claims, using the apparatus according to the disclosure.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the disclosure are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The disclosure is not restricted to the details of any foregoing embodiments. The disclosure extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

### DESCRIPTION OF THE EMBODIMENTS

A representative process for simultaneous deposition onto two opposite sides of a sheetlike substrate using a plurality of linear plasma sources according to the disclosure is performed as follows.

A reaction chamber (10) is provided. The reaction chamber comprises two linear plasma sources (11A, 11B). Each linear plasma source (11A, 11B) comprise a copper rod-shaped antenna (112), which is arranged in a quartz dielectric tube (113). This combination of rod-shaped antenna (12) and dielectric tube (13) is referred to as a coaxial conductor assembly (14). The two linear plasma sources (11A, 11B) are arranged within the reaction chamber (10) such that a sheetlike substrate (15), such as a copper foil (115), can be run between the two linear plasma sources (11A, 11B). The reaction chamber is sparged with nitrogen and then the pressure reduced using a vacuum pump (29) to an atmosphere of approximately 0.1 mbar.

The reaction chamber (10) is equipped with rollers (16), in this case tension rollers (116), which allow the sheetlike substance (15), in this case copper foil (115) to be run between the two linear plasma sources (11A, 11B) in a direction orthogonal to the long axis of the two linear plasma sources (11A, 11B).

The process continues with the introduction of a sheetlike substrate (15), in this case a copper foil (115), comprising two elongate sides (17A, 17B) into the reaction chamber (10). The copper foil is provided from a first drum (18). The drum (18) is unwound in an unwinding chamber (19), through an assembly of tension rollers (116) and into the reaction chamber at a constant velocity of 1 m/s. The copper foil is 600 mm wide, and 1500 m long. The copper foil is optionally pre-heated to 150° C. before being introduced into the reaction chamber (10) by means of one or more heating drums (20). Although not essential, the preheating step aids in obtaining a uniform and strongly adhered coating. The copper foil (115) is moved between the two linear plasma sources (11A, 11B) in a direction orthogonal to the long axis of the two linear plasma sources (11A, 11B) at a first velocity of 1 m/s.

Each of the two linear plasma sources (11A, 11B) is supplied with power to generate linear plasmas in the vicinity of each elongate side of the substrate (119A, 119B). Powers is supplied to the two linear plasma sources (11A, 11B). By ways of no-limiting example, the power is supplied by means of microwave radiation with a frequency of 2.45 GHz from a magnetron (121). The microwave radiation is provided to both ends of each linear plasma source (11A, 11B). The power density per linear plasma source (11A, 11B) is in the order of 4 kW/m, with respect to the length of the linear plasma source (11A, 11B). The provision of such energy is sufficient to provide a linear plasma (28) around each of the two linear plasma sources (11A, 11B), which is uniform along the length of two linear plasma sources (11A, 11B).

A first reactant mixture (22) at a first gas flow rate is introduced the reaction chamber (10) on each of the respective opposite sides (17A, 17B) of the copper foil (115). In this way the first reactant mixture (22) comes into contact with the linear plasma around the linear plasma sources close to the opposite sides (17A, 17B) of the copper foil substrate (115). The first reactant mixture (22) consists of a first reactant (silane, SiH₄), an inert carrier gas (argon) and a second reactant (hydrogen, H₂). Silane (SiH₄) was the source of silicon, whereas argon (Ar) and hydrogen (H₂) were added to stabilize the plasma, influence the material structure and improve the deposition rate. The gas was injected via gas supply manifolds (27), often called “gas showers”, that distribute the gas evenly. The first reactant mixture (22) decomposes upon contact with the plasma generates a chemical reactant species capable of being deposited as a film (23) onto the corresponding sides (17A, 17B) of the copper foil (115), in this case as two layers of amorphous silicon (123A, 123B). In this way, the chemical reactant species is simultaneously deposited onto the first (17A) and second (17B) opposite sides of the copper foil (15) at the same position with respect to the substrate movement direction. This affords a homogeneous film coating of approximately 12 μm thickness on the opposite sides (17A, 17B) of the copper foil (15).

The coated copper foil (124) is then removed from the reaction chamber (10) and rewound onto a storage drum (25) in a winding chamber (30).

The obtained amorphous silicon coated copper foil (124) was found to be coated in a uniformly thick layer of amorphous silicon on both sides of the copper foil (115), and exhibited no warping or delamination of the deposited layers. Such silicon coated copper foils were found to be excellent lithium storage materials for use in lithium batteries. Without wishing to be bound by theory, it is believed that the substantially identical depth of the thin deposited layers of amorphous silicon result in a superior lithium storage materials for use in lithium batteries as compared to materials with two layers of substantially different thicknesses or discontinuous, non-uniformly thick layers.

By way of non-limiting example, an apparatus (26) for simultaneous plasma enhanced chemical vapour deposition onto two opposite sides (17A, 17B) of a sheetlike substrate (15) is depicted in FIG. 1.

FIG. 1 is side-on cross-sectional view of an apparatus (26) for simultaneous plasma enhanced chemical vapour deposition onto two opposite sides (17A, 17B) of a sheetlike substrate (15) according to the present disclosure. the apparatus is depicted in use according to the first embodiment of the claimed process. The depicted apparatus comprises a reaction chamber (10), transport means (31) and support means (32) for introducing a substrate into the reaction chamber (10). By way of non-limiting example, the transport means (31) are provided by the drums (18, 25) and the rollers (16). By way of further non-limiting example, the rollers (16) may be tension rollers (116). By way of non-limiting example, the support means (32) are provided by the rollers (16). These support means ensure that the substrate (15) is supported in the reaction chamber. By way of non-limiting example, the apparatus (26) is configured such that the substrate (15) may be unwound from the drum (18) in the unwinding chamber (19), be introduced into the reaction chamber (10) by the transport means (31) and support means (32) [constituted by drums (18, 25) and rollers (16)], be moved between the linear plasma sources (11A, 11B) such that opposite sides (17A, 17B) of the substrate (15) are brought into proximity to the linear plasma sources (11A, 11B), be removed from the reaction chamber (10) and finally be wound onto a storage drum (25) in a winding chamber.

In this instance, the apparatus (26) comprises two linear plasma sources (11A, 11B). It will be readily appreciated that a greater number of linear plasma sources (11) may be suitably incorporated into such an apparatus (26). The comprises two linear plasma sources (11A, 11B) are configured to allow for simultaneous deposition onto two opposite sides (17A, 17B) of a substrate (15).

The apparatus (26) additionally comprises a power supply means (not depicted) suitable for supplying power to the linear plasma sources (11A, 11B). By way of non-limiting example, a suitable power supply means may be a magnetron (microwave generator) capable of emitting microwave radiation with a frequency of 2.45 GHz from a magnetron (121) and sufficiently powerful to provide 4 KW of energy at this frequency.

The apparatus (26) additionally comprises a gas supply manifold (27). The gas supply manifold (27) is suitable for introducing at least one mixture of reactive species (22) to the reaction chamber (10). By way of non-limiting example, such a gas supply manifold may be a pipe, wherein a portion of the pipe is coaxial with the linear plasma source (11), with a plurality 0.6 mm apertures (first gas ports, 33), with one aperture every 10 mm along the section of the pipe that is coaxial with, and extends substantially along the entire length of the linear plasma source.

The apparatus (26) is configured such that the transport means (31), support means (32) and plurality of linear plasma sources (11) are arranged to allow a substrate (15) to be moved past the plurality of linear plasma sources (11).

The following non-limiting examples further illustrate the objects and advantages of the present disclosure, but the specific materials and amounts thereof, as well as other conditions and details cited in these examples, should not be construed to unduly limit the present disclosure.

The experiments show that sheet-like substrates can be sufficiently cooled by means of radiation.

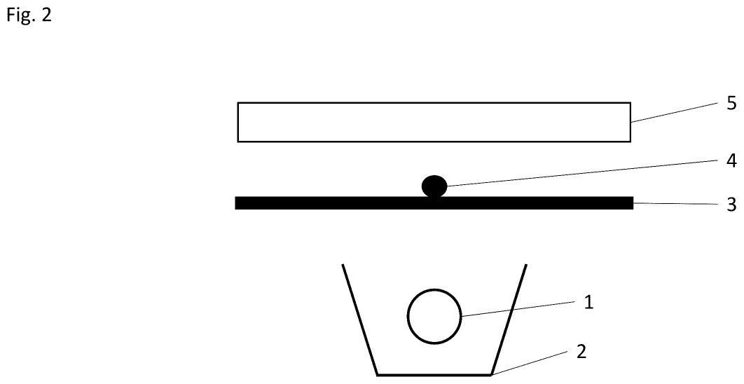

FIG. 2 depicts a side-on cross-sectional view of an experimental setup inside a vacuum chamber. Herein, 1 represents a microwave antenna assembly, 2 a cooled shielding assembly, 3 is a copper foil substrate, 4 a K-type thermocouple, and 5 a cooling plate kept at 20° C.

In this set-up, the sheet of copper foil was of 10 micron thickness, and was suspended above the plasma source in a vacuum chamber. The cooling surface was kept at a temperature of 20° C. by means of water cooling was positioned above the copper foil. The plasma source itself was also water cooled.

The K-type thermocouple was attached to the side of the copper that faced the cooling plate.

The experiment showed that the surface temperature of the copper foil facing the plasma zone was approximately equal to the temperature of the surface facing the cooling plate.

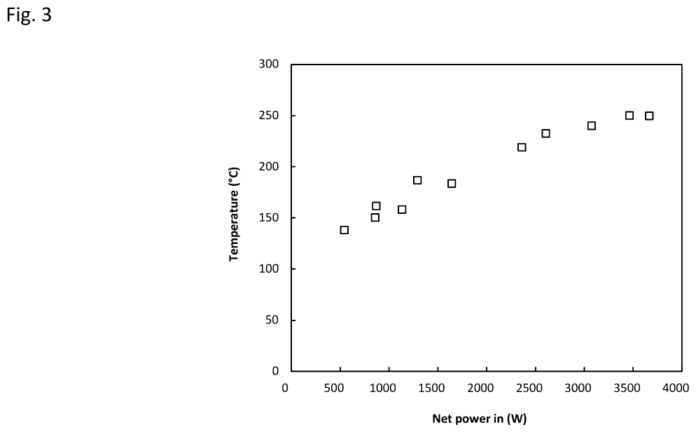

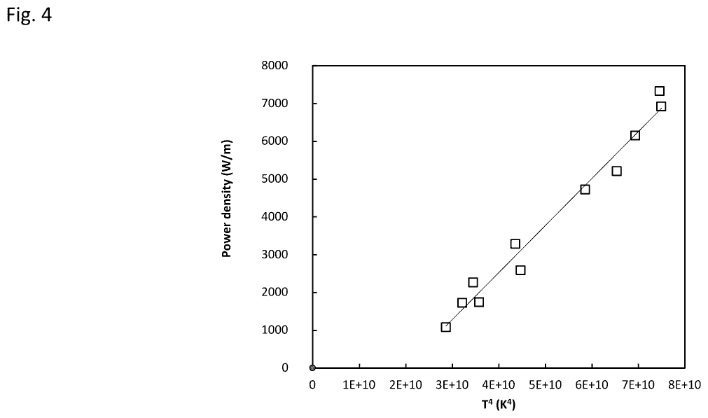

A gas mixture containing H₂, Argon, and Silane in the ratio 50/70/300 was fed to the plasma source. The vacuum pressure was kept at 0.1 mbar. The power input of the microwave was varied in a range between 500 and 4000 W. The resulting foil temperature, given in FIG. 3, shows that the temperature strongly depended on the net power input, whereby higher power input lead to a higher temperature. This is illustrated in FIG. 4, which plots the measured net power input versus the fourth power of temperature (T⁴, in K⁴), confirming the assumption that radiation intensity of a black-body radiator is a function of T⁴. The resulting graph was found to follow a linear trend, indicating that indeed in this range of power input and temperature, radiation is the dominant mechanism for web cooling.

It was also found that the influence of heat convection and conduction in the presence of an actively cooled surface on foil temperature was however of a negligible effect. This may be in part due to the low operating pressure of 0.1 mbar, which means that the plasma gas has a low density and the ability of the gas to influence the foil temperature is limited. Also, it was found that in the high-temperature zone, the influence of heat conduction was limited.

Accordingly, the presence of a cooled shielding assembly according to the present disclosure effectively allowed to control the foil temperature, and hence deposition of the film with the desired morphology, in particular for a double-sided deposition.

### LIST OF REFERENCES

Similar reference numbers used in the description to indicate similar elements (but only differ in the hundreds) are implicitly included [e.g. 101 and 201].
1 Microwave assembly.
2 Cooled shielding assembly
3 Copper foil substrate
4 K-type thermocouple
5 Cooling plate
10 Reaction chamber
11 Linear plasma source
12 Rod-shaped antenna
13 Dielectric tube
14 Coaxial conductor assembly
15 Sheetlike substrate
16 Rollers
17 Elongate side
18 Drum
19 Unwinding chamber
20 Heating drums
21 Power supply means
22 First reactant mixture
23 Film
24 Coated sheetlike substrate
25 Storage drum
26 Apparatus
27 Gas supply manifold
28 Linear plasma
29 Vacuum pump
30 Winding chamber
31 Transport means
32 Support means
33 First gas ports
34 Deposition zone
37 Radiative cooling plate
112 Copper rod-shaped antenna
113 Quartz dielectric tube
115 Copper foil
116 Tension rollers
121 Magnetron (microwave radiation source)
123 Layer of amorphous silicon
124 Coated copper foil

1. A process for simultaneous deposition onto two opposite sides of a sheetlike substrate using a plurality of linear plasma sources, comprising the steps:
providing a reaction chamber comprising a gaseous atmosphere; and at least two linear plasma sources positioned in the chamber,
introducing a sheet-like electrically conductive substrate comprising two elongate sides into the reaction chamber, and moving the substrate between the at least two linear plasma sources at a first velocity;
supplying power to the linear plasma sources to generate linear plasmas in the vicinity of each side of the substrate;
introducing at least one reactant mixture, at a first gas flow rate, into the reaction chamber on each of the respective opposite sides of the substrate, the composition of the mixture being such that, upon contact with the plasma, the reactant mixture decomposes and generates a chemical reactant species capable of being deposited as a film onto the corresponding side of the substrate;
radiatively cooling the substrate between the first deposition zone and the second deposition zone;
allowing the chemical reactant species to simultaneously be deposited onto the first and second opposite sides of the substrate at the same position with respect to the substrate movement direction;
to obtain a substrate comprising a coated homogeneous film of desired thickness on the opposite sides of the substrate.

2. The process according to claim 1, where the substrate comprises metal, metal alloy and/or electrically conductive polymers.

3. The process according to claim 1, wherein the composition of the at least one reactant mixture introduced into the reaction chamber on each side of the substrate is essentially identical.

4. The process according to claim 1, wherein the at least one reactant mixture introduced into the reaction chamber on each side of the substrate is at least a first mixture and a second mixture, respectively, whereby the least a first and at least second reactant mixture differ, whereby each is converted into a reactant species capable of being deposited as a film onto the respective sides of the substrate.

5. The process according to claim 1, wherein the linear plasma sources are linear microwave plasma sources.

6. The process according to claim 5, wherein the microwaves are generated at frequency in the range of from 0.9-5.8 GHZ.

7. The process according to claim 1, wherein the process is conducted at a pressure of 0.05 to 0.5 mbar in the reaction chamber.

8. The process according to claim 1, wherein the process has a dynamic deposition rate in the range of from 0.05 to 200 nm·m·s⁻¹.

9. The process according to claim 1, wherein the substrate is a film, the film having a width of from 100 to 1800 mm.

10. The process according to claim 1, wherein the substrate is a film, having a length in the range of from 100 to 2000 m.

11. (canceled)

12. The process according to claim 1, wherein the process comprises simultaneous deposition of a lithium storage material onto two opposite sides of a substrate using a plurality of linear plasma sources.

13. (canceled)

14. (canceled)

15. (canceled)

16. (canceled)

17. (canceled)

18. (canceled)

19. The process according to claim 1, wherein the process comprises simultaneously depositing an electronically conductive material onto two opposite sides of a substrate using a plurality of linear plasma sources.

20. The process according to claim 1, wherein the reactant mixture is introduced into the reaction chamber on one or both sides of the substrate as a first gas mixture and a second gas mixture.

21. The process according to claim 20, wherein the first gas mixture comprises one or more chemically inert carrier gases selected from nitrogen, helium, argon, or combinations thereof, and/or wherein the first gas mixture comprises a reactant gas selected from nitrogen, hydrogen, oxygen, ammonia, nitrous oxide, nitrogen trifluoride, methane, acetylene, ethane, ethene, propane, propene or any combination of these gasses, and/or wherein the first gas composition comprises a chemically inert carrier gas and a reactive gas or a combination of these gasses and the reactive gas is selected from hydrogen, oxygen ammonia, nitrous oxide, nitrogen trifluoride, methane, acetylene ethane, ethene, propane, and/or propene, and/or wherein the first gas composition comprises a chemically inert carrier gas and a reactive gas, and wherein the second gas composition comprises a precursor gas.

22. (canceled)

23. (canceled)

24. (canceled)

25. The process according to claim 20, wherein the second gas composition comprises a precursor gas.

26. (canceled)

27. (canceled)

28. An apparatus for simultaneous plasma enhanced chemical vapour deposition onto two opposite sides of a sheetlike substrate, the apparatus comprising:
a reaction chamber;
one or more transport means and/or support means for introducing a substrate into the chamber;
a plurality of linear plasma sources, wherein at least two linear plasma sources are arranged to allow simultaneous deposition onto two opposite sides of a substrate;
power supply means for supplying power to the linear plasma sources;
a gas supply manifold for introducing the at least one mixture of reactive species to the reaction chamber;
radiative cooling plates
wherein the transport means, support means and plurality of linear plasma sources are arranged to allow the substrate to be moved at an essentially constant velocity past the plurality of linear plasma sources.

29. The apparatus according to claim 28, wherein the linear plasma sources are linear microwave plasma sources and wherein the power supply means additionally comprises a microwave generator.

30. The apparatus according to claim 28, wherein the means for introducing the at least one mixture of reactive species to the reaction chamber is a gas supply manifold.

31. The apparatus according to claim 28, wherein the means for introducing the at least one mixture of reactive species to the reaction chamber is a gas supply manifold, and/or wherein the radiative cooling plates are located directly opposite to the linear plasma sources.

32. (canceled)

33. The process according to claim 1, using
an apparatus, wherein the apparatus comprises:
a reaction chamber;
one or more transport means and/or support means for introducing a substrate into the chamber;
a plurality of linear plasma sources, wherein at least two linear plasma sources are arranged to allow simultaneous deposition onto two opposite sides of a substrate;
power supply means for supplying power to the linear plasma sources;
a gas supply manifold for introducing the at least one mixture of reactive species to the reaction chamber;
radiative cooling plates
wherein the transport means, support means and plurality of linear plasma sources are arranged to allow the substrate to be moved at an essentially constant velocity past the plurality of linear plasma sources.
